(19) United States
(12) Patent Application Publication
(10) Pub. No.: US 2003/0073255 A1
(43) Pub. Date: Apr. 17, 2003

(54) Novel self monitoring process for ultra thin gate oxidation

(76) Inventors: Sundar Narayanan, Santa Clara, CA (US); Krishnaswamy Ramkumar, San Jose, CA (US)

Correspondence Address: Supervisor, Patent Prosecution Services, PIPER MARBURY RUDNICK & WOLFE LLP, 1200 Nineteenth Street, N.W., Washington, DC, 20036-2412, US

(21) Appl. No.: 09/975,257

(22) Filed: Oct. 12, 2001

(51) Int. Cl. H01L 21/66; G01R 31/26

(52) U.S. Cl. 438/14; 438/769; 438/770

(57) ABSTRACT

A method of determining the nitrogen content of a nitrided gate oxide layer on a semiconductor substrate is provided. The method comprises steps of: oxidizing the nitrided gate oxide layer; measuring the thickness of the oxidized nitrided gate oxide layer; optionally determining the change in thickness of the oxidized nitrided gate oxide layer; and determining if the measured thickness or calculated change in thickness exceeds a predetermined level. The oxidizing step may be conducted in a conventional furnace or in a rapid thermal processing (RTP) chamber. In a preferred embodiment of the invention, the method further comprises measuring the thickness of the oxidized nitrided gate oxide layer for a plurality of samples having known nitrogen contents and performing a least squares regression analysis on the data to generate a calibration curve for nitrogen content as a function of oxidized nitrided gate oxide thickness. The calibration curve can be used to correlate the oxidized nitrided gate oxide thickness with the nitrogen content of the nitrided gate oxide layer. A system and a method for statistical process control of the nitrogen content of nitrided gate oxide layers using the measured thickness of the oxidized nitrided gate oxide layer is also provided.

### BACKGROUND OF THE INVENTION

1. Field of the Invention

The invention relates generally to a method of determining the nitrogen content of an oxide layer and, in particular, to a method for determining the nitrogen content of nitrided gate oxide layers on semiconductor substrates.

2. Background of the Technology

Semiconductor devices such as MOS (metal-oxide-semiconductor) devices are typically formed on a substrate such as a silicon wafer. Typically, one or more films of an insulating material such as silicon dioxide are formed on the substrate over which is formed a gate electrode. The insulating film formed between the gate electrode and the silicon substrate is referred to as the gate oxide or gate dielectric. A widely employed type of MOS integrated circuit is a metal-oxide-semiconductor field-effect transistor, or MOSFET.

Boron doping of the gate electrodes of MOS devices (e.g., p⁺ gates) has been used to improve device performance by reducing short-channel effects and lowering threshold voltages. Typically, boron is implanted into the poly-Si gate at sufficiently high concentrations to ensure adequate conductance of the poly-Si gate. With the continued push for smaller and smaller MOSFET dimensions, however, higher active dopant concentrations are required. When boron is used as the dopant for p⁺ gates, boron atoms in the gate layer can diffuse into the gate dielectric during downstream processing. Boron, which is a relatively small atom, has a very high diffusion coefficient in both silicon and silicon dioxide at temperatures encountered during processing. Further, it is necessary to activate the boron dopant after implantation with a high-temperature anneal which is typically conducted at temperatures in the range of 950-1050° C. During this high-temperature anneal, boron diffusion can be exacerbated.

Boron penetration into and through the gate dielectric can also have significant effects on device characteristics. First, boron penetration through the gate dielectric and into the channel can influence device performance. Boron diffusion into the channel, for example, can result in a shift in the threshold voltage of the device and can even result in charge-induced damage and breakdown during device operation. Also, as boron penetrates into the gate dielectric layer, the capacitance-voltage (C-V) or flat-band voltage of the device can shift which can degrade device performance. The presence of boron in the gate oxide film can also degrade the quality of the gate oxide film.

The reduction of boron penetration is particularly important in light of the decreasing dielectric layer thicknesses of modem MOS devices. It is known to incorporate nitrogen into an oxide film to retard the effects of boron penetration. The amount of nitrogen incorporated into the gate oxide can determine the effectiveness of the oxide layer in blocking boron diffusion through the gate oxide. The amount of nitrogen doping required in a particular application, however, is dictated in part by the thermal cycles to which the device is subjected after deposition and doping of the gate electrode. Typical amounts of nitrogen required for adequate levels of boron diffusion blocking are in the range of 1 to 3 at. %.

It has also been recognized that the presence of nitrogen lowers the diffusion rates for oxygen, nitric oxide, and other dopants, significantly slowing the rate of further oxidation or nitridation of the Si interface. See, for example, Gusev et al., “Growth and Characterization of Ultrathin Nitrided Silicon Oxide Films”, IBM Journal of Research and Development, Vol. 43, No. 3, May 1999. This effect has also been recognized in U.S. Pat. Nos. 5,880,040 and 6,060,374.

The nitrogen content of the nitrided gate dielectric layer is therefore an important variable in determining device performance. Nitrogen content, however, can be difficult to measure due to the relatively low nitrogen contents and the relatively small thickness of typical gate oxide films (i.e., less than 5 nm).

Secondary ion mass spectroscopy (SIMS) is a standard technique used in the semiconductor industry to monitor concentration profiles in semiconductor structures. SIMS, for example, has been utilized to study nitrogen concentrations, depth profiles, nitrogen bonding, and the microstructure of oxynitrided films. The SIMS technique has very high sensitivity (on the order of 0.001 at. %). Further, SIMS testing can be performed rapidly and shows good long-term reproducibility.

For all of its advantages, however, SIMS cannot be done in a manufacturing facility to test production lots and get a pass fail criteria instantly and non-destructively. SIMS is not, therefore conducive for use with statistical process control (SPC). Further, the cost of SIMS can be prohibitive.

There still exists a need for a method of determining the nitrogen content of nitrided gate oxide layers rapidly and in a manner which can be used for statistical process control of gate oxide deposition processes in semiconductor manufacture.

### SUMMARY OF THE INVENTION

In a first aspect of the invention, a method of determining the nitrogen content of a nitrided gate oxide layer on a semiconductor substrate is provided. The method comprises steps of: oxidizing the nitrided gate oxide layer; measuring the thickness of the oxidized nitrided gate oxide layer; optionally calculating the change in thickness of the oxidized nitrided gate oxide layer; and determining if the measured thickness or calculated change in thickness exceeds a predetermined value. The oxidizing step may be conducted in a conventional furnace or in a rapid thermal processing (RTP) chamber. In a preferred embodiment of the aforementioned process, the measured oxidized nitrided gate oxide layer thickness or calculated change in thickness is correlated with the nitrogen content of the nitrided gate oxide layer. The correlation step can be performed by measuring the oxidized nitrided gate oxide thickness for a plurality of samples having nitrided gate oxide layers with known nitrogen contents; optionally calculating the change in oxidized nitrided gate oxide thickness; and performing a least squares regression analysis to generate a calibration curve for nitrogen content as a function of oxidized nitrided gate oxide thickness or oxidized nitrided gate oxide thickness change.

In a second aspect of the invention, a method for monitoring the nitrogen content of an oxidized nitrided gate oxide layer on a semiconductor substrate is provided. The method comprises: a) measuring the thickness of the oxidized nitrided gate oxide layer with a film thickness measuring device for each substrate in a batch of semiconductor substrates; b) collecting batch data on the thickness of the oxidized nitrided gate oxide layer on a computer in communication with the thickness measuring device; c) storing the gate oxide thickness batch data in a data base; d) computing a batch average value for the thickness of the oxidized nitrided gate oxide layer; e) storing the batch average thickness value on the computer; f) repeating steps (a) through (e) above for additional batches of semiconductor substrates; g) determining process control limits from the stored average batch values; and h) monitoring the nitrogen content by oxidizing a semiconductor substrate having a nitrided gate oxide layer, measuring the oxidized nitrided gate oxide layer thickness and comparing the measured value to the process control limits.

According to third aspect of the invention, a system for statistical process control of gate oxide nitridation of a semiconductor substrate is provided. The system comprises: a furnace for oxidizing a nitrided gate oxide layer on a semiconductor substrate; a film thickness measuring device adapted to measure the thickness of the oxidized nitrided gate oxide layer; and a computer in communication with the film thickness measuring device. The computer is adapted to monitor the thickness of the oxidized nitrided gate oxide layer after an oxidation step conducted in the furnace and to store the measured thickness values collected from the thickness measuring device. The computer is also adapted to retrieve and analyze the measured thickness values. According to a preferred embodiment of the aforementioned system, the computer is adapted to calculate process control limits from the measured film thickness data.

### BRIEF DESCRIPTION OF THE FIGURES

The invention will be described with reference to the accompanying figures, wherein:

FIG. 1 shows cross sections of the semiconductor substrate during various stages of the formation of the gate oxide layer according to the invention wherein FIG. 1A shows the cross-section after initial oxide formation, FIG. 1B shows the cross section after nitridation, and FIG. 1C shows the cross-section after oxidation of the nitrided gate oxide layer;

FIG. 2 is a graph showing a calibration curve for nitrogen content as a function of the change in thickness of the oxidized nitrided gate oxide layer according to the invention;

FIG. 3 is a flowchart showing the steps involved in a statistical process control method according to the present invention; and

FIG. 4 is a flowchart showing a process control system according to the invention.

### DETAILED DESCRIPTION OF THE INVENTION

The present invention provides a method of determining the nitrogen content of nitrided gate oxide layers. According to the invention, the nitrided gate oxide layer of a semiconductor device is oxidized and the thickness of the oxidized nitrided gate oxide layer is measured. From the measured gate oxide thickness value, the change in the thickness of the oxidized nitrided gate oxide layer can be determined. The measured value of oxidized nitrided gate oxide thickness (or the calculated change in thickness of the oxidized nitrided gate oxide layer) can then be correlated to a nitrogen content of the nitrided gate oxide layer. Alternatively, the measured thickness or calculated change in thickness of the oxidized nitrided gate oxide layer can be used as a pass/fail criterion. For example, if the measured thickness exceeds a predetermined value, it can be immediately determined that the nitrided gate oxide layer has an insufficient nitrogen content (e.g., to prevent boron diffusion and premature device failure). The present invention thus provides a means for readily ascertaining whether the gate oxide layer has been nitrided to a sufficient extent (e.g., to an extent sufficient to prevent boron diffusion through the gate dielectric and into the channel) during the nitridation step.

According to a preferred embodiment of the invention, the method comprises steps of: oxidizing a nitrided gate oxide layer on a semiconductor substrate; measuring the thickness of the oxidized nitrided gate oxide layer; and, optionally, determining the change in thickness of the oxidized nitrided gate oxide layer during the oxidation step. In a preferred embodiment of the invention, the method further comprises a step of forming an initial oxide layer by oxidizing the semiconductor substrate and a step of nitriding the initial oxide layer prior to the oxidizing step. According to a preferred embodiment of the present invention, the nitridation and oxidation steps can be conducted in the same chamber or tool. The initial oxide formation can also be conducted in the same tool. Alternatively, the substrate can be transferred out of the nitridation tool after the nitridation step and the oxidation step can be conducted in a separate tool.

The thickness or change in thickness of the oxidized nitrided gate oxide layer according to the invention can provide an indication of the nitrogen content of the nitrided gate oxide layer. The measured thickness of the nitrided gate oxide layer can be easily and rapidly determined using conventional metrology equipment. By comparing the measured thickness or the calculated change in thickness to control limits for these variables determined using statistical process control, the nitridation process can be monitored and malfunctions in the process can be readily identified. For example, if the nitrogen content of the nitrided gate oxide layer falls below an acceptable limit, the measured thickness or calculated change in thickness of the oxidized nitrided gate oxide layer will increase. This increase in thickness, which is an indirect measure of the nitrogen content of the nitrided gate oxide layer, can be used as an indication of a malfunction in the process.

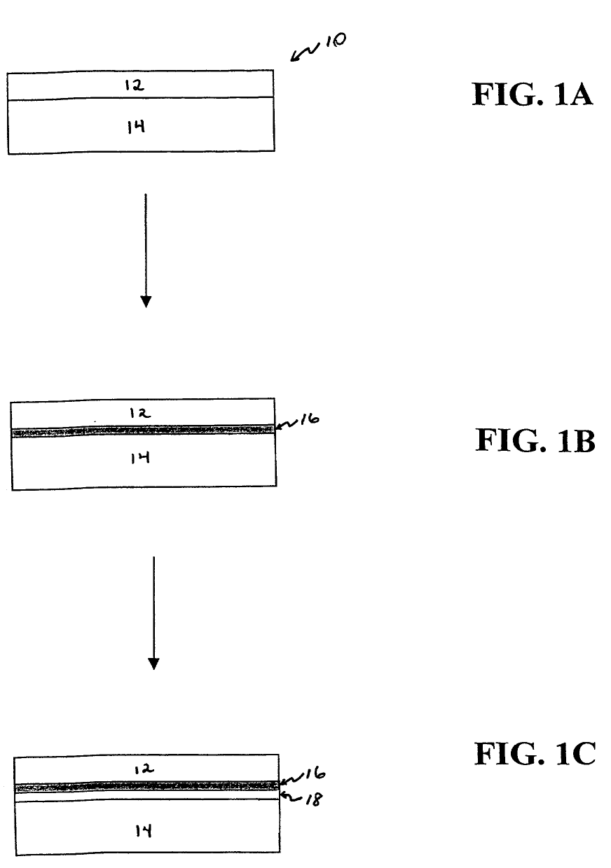

FIG. 1 shows the cross section of a semiconductor substrate during an oxidation process according to the invention. FIG. 1A is a cross-sectional representation showing a semiconductor substrate 10 comprising an oxide film 12 (i.e., SiO₂) on a silicon layer 14. FIG. 1B is a cross-sectional representation of the silicon substrate 10 of FIG. 1A after nitridation showing a nitride layer 16 formed at the Si/SiO₂ interface. FIG. 1C is a cross-sectional representation of the substrate of FIG. 1B after oxidation of the nitrided oxide layer showing a second oxidized layer 18 (i.e., a reoxidized layer) formed between the nitride layer 16 and the silicon layer 14.

The initial oxide layer can be a thermal oxide layer formed on the surface of a semiconductor substrate in a conventional furnace or in a rapid thermal processing (RTP) chamber. The RTP chamber is typically a single wafer tool whereas the use of a convention furnace allows for a plurality of wafers to be processed (e.g., oxidized, nitrided, or reoxidized) at the same time. As with initial oxide formation, oxidation of the nitrided gate oxide layer can also be conducted in a conventional furnace or in an RTP chamber. Other types of furnaces (e.g., a CVD furnace) used in the semiconductor industry for oxidizing substrates, however, can also be employed for initial oxide formation and/or reoxidation.

The initial oxide layer may be a wet oxide or a dry oxide layer. Dry oxide layers are preferred. The thickness of the initial oxide layer will vary depending upon the characteristics desired from the device being manufacture. In a preferred embodiment of the invention, the initial oxide layer will have a thickness of from 5-24 Angstroms.

The nitridation step according to the invention is preferably conducted using a high purity nitrogen containing gas (e.g., 99.99 or 99.999% nitric oxide gas). Other nitrogen containing gases known in the art for nitridation such as N₂O, however, can also be used. Nitridation is preferably conducted in-situ in the same furnace or RTP chamber as the initial oxidation step.

The oxidation of the nitrided gate oxide layer according to the invention is preferably conducted at a temperature of about 800° C. to about 1025° C., more preferably at a temperature of about 900° C. to about 1025° C. Oxidation can be conducted using a high purity (e.g., 99.5% purity) oxygen gas. As set forth above, reoxidation can be carried out in a conventional furnace or RTP chamber as well as any other type of oxidizing furnace known in the art (e.g., CVD furnace). According to a preferred embodiment of the invention, oxidation is conducted for a time of 10 minutes or less.

The oxidation conditions (e.g., time and temperature) can be adjusted to maximize the change in oxide thickness upon reoxidation of the nitrided gate oxide layer. In this manner, the sensitivity of the process to the nitrogen content of the gate oxide layer can be increased allowing for improved resolution of the nitrogen content of the gate oxide layer. As a result, improved statistical process control of the nitrogen content of the gate oxide layer can be realized.

The thickness of the oxidized nitrided gate oxide layer can be determined by any film thickness measurement technique known in the art. For example, film thickness can be measured using reflectometry (e.g., spectroscopic or single wavelength). According to a preferred embodiment of the invention, film thickness is measured using single wavelength reflectometry. When an RTP chamber or other single wafer processing tool is used for reoxidation, the film thickness measuring device can be mounted in the process chamber and the oxide film thickness can be measured in situ. Alternatively, the wafer can be transferred out of the reoxidation chamber and the thickness of the oxidized nitrided gate oxide layer can be measured in a separate tool.

The change in thickness of the oxidized nitrided gate oxide layer can be calculated by determining the initial gate oxide thickness (e.g., by measuring the thickness of the gate oxide layer prior to the oxidation step) and taking the difference between the measured oxidized nitrided gate oxide layer thickness and the initial gate oxide thickness. The initial gate oxide thickness can be measured either before the nitridation step or after the nitridation step. The initial gate oxide thickness according to the invention can also be estimated. For example, the initial gate oxide thickness can be estimated from gate oxide thickness data previously collected for the initial oxide formation process. The previously collected data can be data taken under the same process conditions. Alternatively, the previously collected data can be data taken under different process conditions and the estimate can be interpolated or extrapolated therefrom.

According to the invention, the thickness or change in thickness during oxidation of the oxidized nitrided gate oxide layer can be correlated to the nitrogen content of the gate oxide layer. A calibration curve for the nitrogen content as a function of the measured thickness or the calculated change in thickness can then be generated for the reoxidation conditions being employed in the furnace or RTP. The nitrogen content of the samples used to generate the calibration curve can be determined using standard analytical techniques such as secondary ion mass spectroscopy (SIMS). Other techniques known in the art such as nuclear reaction analysis (NRA), medium energy ion scattering (MEIS), x-ray photoelectron spectroscopy (XPS), Auger electron spectroscopy (AES), Fourier transform infrared spectroscopy (FTIR), and spectroscopic ellipsometry can also be employed.

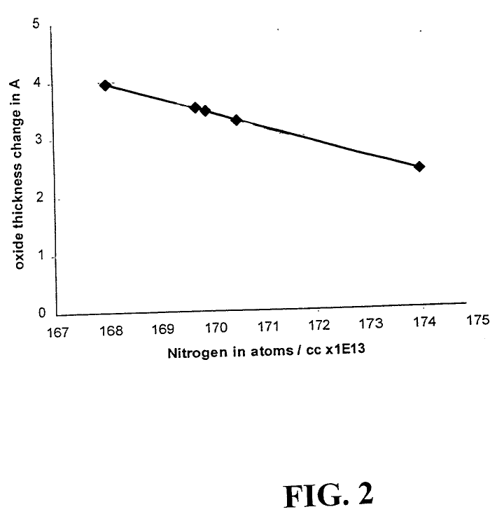

FIG. 2 is a graph showing the change in thickness of the oxidized nitrided gate oxide layer in angstroms plotted as a function of the nitrogen content of the nitrided gate oxide layer. As can be seen from FIG. 2, the change in thickness of the oxidized nitrided gate oxide layer decreases with increasing nitrogen content of the gate oxide layer. A least squares regression analysis produced a linear fit to the data as set forth below:

y=−0.2621(x)+47.978

where y is the oxide thickness change in angstroms and x is the nitrogen content (nitrogen atoms/cc)×10¹³ of the gate oxide layer. The nitrogen content of the gate oxide layer was measured using SIMS.

### EXAMPLE

An experiment was conducted to demonstrate the effect of the presence of even small amounts of nitrogen in the gate oxide layer on the change in thickness of the oxidized nitrided gate oxide layer.

A silicon wafer was placed in a furnace and a blanket thermal oxide layer was formed thereon. The thermal oxide layer was then nitrided in a furnace using nitric oxide (NO) gas. The thickness of the nitrided oxide layer was then measured. The nitrided oxide layer was then oxidized in the furnace using oxygen gas. Film thickness was again measured and the change in thickness as during reoxidation was calculated. The same procedure as outlined above was conducted for a second silicon wafer wherein the nitriding step was omitted.

Table I shows the measured oxide thickness change for the two wafers.

TABLE I

| | Film | | |
|---|---|---|---|
| | Thickness | Film Thickness | Change in |
| | before | after | Film |
| | Re-Oxidation | Re-Oxidation | Thickness |
| Wafer Description | (Angstroms) | (Angstroms) | (Å) |
| With nitridation step | 22.43 | 26.6 | 4.17 |
| Without nitridation step | 23.19 | 101.10 | 77.91 |

As can be seen from Table I, the incorporation of nitrogen into the gate oxide results in a significantly smaller increase in thickness of the oxidized nitrided gate oxide layer upon oxidation.

The oxidation of the nitrided gate oxide layer according to the invention can also impart beneficial properties to the nitrided gate oxide layer by moving the nitrided region away from the substrate/oxide (e.g., Si/SiO₂) interface. As a result, carrier mobility and, consequently, the speed of the device can be improved. Further, it has been discovered that too much nitrogen incorporated near the Si/SiO₂ interface can cause an undesirable shift in the threshold voltage of the semiconductor device. Additionally, it has been found that moving the nitrided region closer to the poly-Si/SiO₂ interface can help reduce the extent of boron penetration into the gate oxide layer. As a result, device performance can be improved by reoxidizing the gate oxide layer according to the invention.

The method of determining the nitrogen content of the gate oxide layer according to the invention allows for statistical process control (SPC) of the nitrogen content of the gate oxide layer as well as the nitriding efficiency of the nitridation process. An example of statistical process control for use in semiconductor processing is disclosed in U.S. Pat. No. 5,862,054.

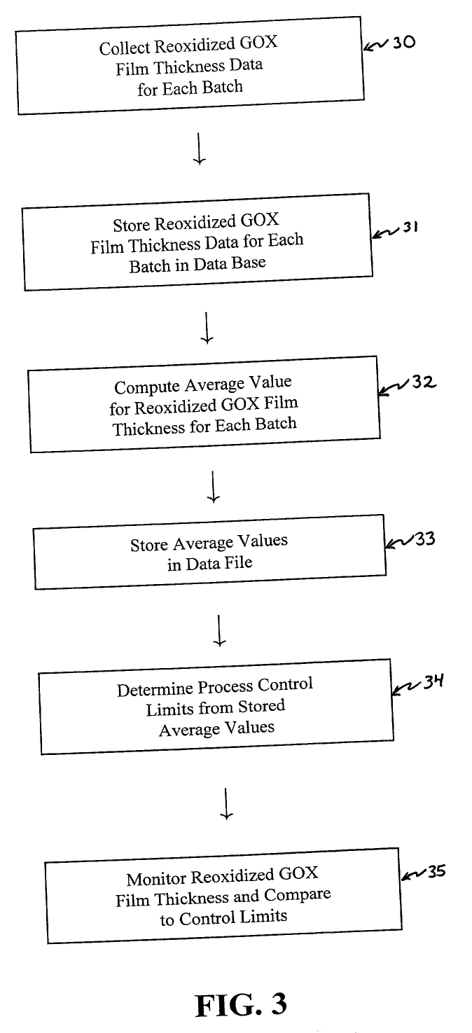

FIG. 3 is a flow chart illustrating a process for collecting and storing oxidized nitrided gate oxide thickness data and computing process control limits from the stored data. As shown in FIG. 3, a process control computer collects data for measured thickness of the oxidized nitrided gate oxide layer for each batch of semiconductor substrates being processed 30. The process control computer is in communication with a thickness measuring device (e.g., a spectrometer). The measured gate oxide thickness data is stored in a data base 31 in the computer's memory. An average value 32 is then computed for the measured oxidized nitrided gate oxide thickness for each batch of substrates being processed. These average values are stored in a batch average data file 33 in the memory of the process control computer. The process control limits for oxidized nitrided gate oxide layer thickness 34 are then calculated using data in batch average data file 33. The oxidized nitrided gate oxide film thickness can then be monitored 35 and the measured values of oxidized nitrided gate oxide thickness compared to control limits 34.

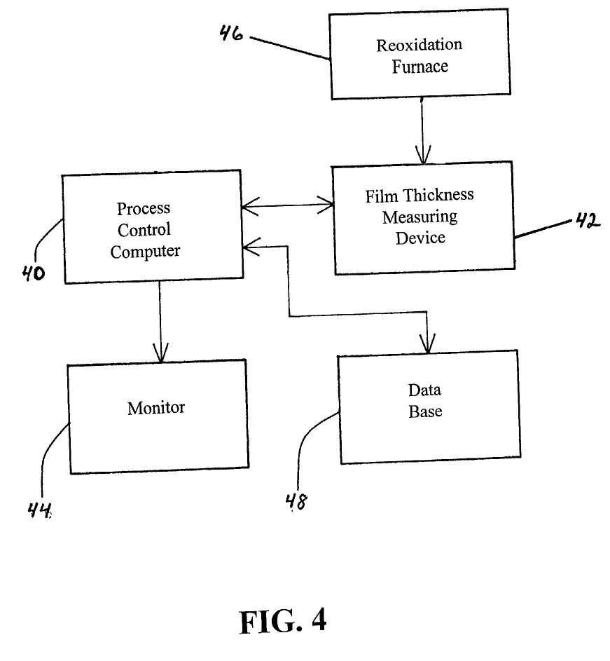

FIG. 4 illustrates a flowchart of a system for monitoring the oxidized nitrided gate oxide film thickness according to the invention. According to FIG. 4, a computer (e.g., a process control computer) 40 is in communication with a film thickness measuring device 42 for the purpose of collecting oxidized nitrided gate oxide film thickness data for analysis and display on monitor 44. Film thickness is measured after oxidation of the nitrided gate oxide layer in an oxidation furnace 46. The process control computer 40 contains a data base 48 which can be used to store the film thickness data. The film thickness data can be used to compute parameters such as Cₚ and Cₚₖ for SPC analysis as well as to compute various process parameter trends. The monitor 44 can be used to display various data including charts and graphs of the film thickness data, as well as data values for SPC analysis such as Cₚ and Cₚₖ.

The data can be displayed on monitor 44 in the form of graphs and charts showing, for example, the trend of the film thickness data. Along with the graphics, specific values for Cₚ and Cₚₖ from SPC analysis can also be displayed on monitor 44. An alarm indicator (not shown) can also be included to indicate when the process is out of control (i.e., when the measured film thickness value exceeds the calculated control limits).

A gate electrode layer can be deposited over the nitrided gate oxide layer or the oxidized nitrided gate oxide layer according to the invention. The gate electrode layer can be any art recognized material. For example, the gate electrode material can be a polysilicon or a polycrystalline silicon germanium layer. The gate electrode may also be a stack comprising a polysilicon or a polycrystalline silicon germanium layer and one or more additional layers. Suitable additional layers include tungsten and tungsten silicide. The gate electrode may also be doped with a dopant. Any art recognized dopant for gate electrodes (e.g., boron) can be employed according to the invention.

According to a preferred embodiment of the invention, the measured thickness (or calculated change in thickness) of the oxidized nitrided gate oxide layer will correspond to a nitrogen content of the nitrided gate oxide layer sufficient to prevent diffusion of dopant atoms (e.g., boron) through the gate oxide layer and into the semiconductor substrate. The desired nitrogen content for a particular device can be determined by experimentation.

These and other modifications and variations to the present invention may be practiced by those of ordinary skill in the art, without departing from the spirit and scope of the present invention. Furthermore, those of ordinary skill in the art will appreciate that the foregoing description is by way of example only, and is not intended to limit the invention.

What is claimed is:

1. A method of determining the nitrogen content of a nitrided gate oxide layer on a semiconductor substrate comprising:
oxidizing the nitrided gate oxide layer on the substrate;
measuring the thickness of the oxidized nitrided gate oxide layer;
optionally calculating the change in thickness of the oxidized nitrided gate oxide layer; and
determining if the measured thickness or calculated change in thickness of the oxidized nitrided gate oxide layer exceeds a predetermined value.

2. The method of claim 1, wherein the oxidizing step comprises rapid thermal oxidation of the nitrided gate oxide layer in a rapid thermal processing (RTP) chamber.

3. The method of claim 1, further comprising correlating the measured thickness or change in thickness of the oxidized nitrided gate oxide layer with the nitrogen content of the gate oxide layer.

4. The method of claim 1, further comprising nitriding a gate oxide layer prior to the oxidizing step.

5. The method of claim 4, further comprising forming an initial oxide layer on the substrate prior to the nitriding step.

6. The method of claim 3, wherein the correlating step comprises:
measuring the oxidized nitrided gate oxide thickness for a plurality of samples each having a known nitrogen content;
optionally calculating the change in thickness after oxidizing the nitrided gate oxide layer for each sample; and
performing a least squares regression analysis to generate a calibration curve for nitrogen content of the nitrided gate oxide as a function of oxidized nitrided gate oxide thickness or change in oxidized nitrided gate oxide thickness.

7. The method of claim 1, wherein the step of determining the change in thickness of the oxidized nitrided gate oxide layer comprises determining the initial gate oxide thickness by measuring the thickness of the gate oxide layer prior to the oxidation step and calculating the difference between the measured oxidized nitrided gate oxide layer thickness and the initial gate oxide thickness.

8. The method of claim 7, wherein the initial gate oxide thickness is measured before the nitridation step.

9. The method of claim 7, wherein the initial gate oxide thickness is measured after the nitridation step.

10. The method of claim 1, wherein the step of determining the change in thickness of the oxidized nitrided gate oxide layer comprises determining the initial gate oxide thickness by estimating the thickness of the gate oxide layer prior to the oxidation step and calculating the difference between the measured oxidized nitrided gate oxide layer thickness and the initial gate oxide thickness.

11. The method of claim 10, wherein the initial gate oxide thickness is estimated from previously collected gate oxide thickness data.

12. The method of claim 1, further comprising a step of forming a gate electrode layer over the gate oxide layer.

13. The method of claim 12, further comprising a step of implanting boron atoms in the gate electrode layer.

14. The method of claim 12, wherein the predetermined value corresponds to a nitrogen content sufficient to prevent boron atoms from diffusing through the gate oxide layer and into the semiconductor substrate.

15. The method of claim 1, wherein the oxidation step is conducted at a temperature of 900 to 1025° C.

16. The method of claim 15, wherein the oxidation step is conducted for 10 minutes or less.

17. The method of claim 4, wherein the oxidizing step is performed in the same tool as the nitridation step.

18. The method of claim 4, wherein the nitridation step is performed in a first tool and the substrate is transferred to a different tool for the oxidizing step.

19. A method for monitoring the nitrogen content of a nitrided gate oxide layer on a semiconductor substrate wherein the nitrided gate oxide layer is oxidized, the method comprising:
a) measuring the thickness of the oxidized nitrided gate oxide layer with a film thickness measuring device for each substrate in a batch of semiconductor substrates;
b) collecting data on the thickness of the oxidized nitrided gate oxide layer for each substrate in the batch on a computer in communication with the film thickness measuring device;
c) storing the oxidized nitrided gate oxide thickness data for the batch in a data base;
d) computing a batch average value for the thickness of the oxidized nitrided gate layer;
e) storing the batch average value on the computer;
f) repeating steps (a) through (e) above for additional batches of semiconductor substrates;
g) determining process control limits from the stored batch average values; and
h) monitoring the nitrogen content by oxidizing a semiconductor substrate having a nitrided gate oxide layer, measuring the oxidized nitrided gate oxide layer thickness and comparing the measured value to the process control limits.

20. A monitoring system for statistical process control of the nitrogen content of a nitrided gate oxide layer on a semiconductor substrate, the system comprising:
a furnace for oxidizing a nitrided gate oxide layer on said semiconductor substrate;
a film thickness measuring device adapted to measure the thickness of the oxidized nitrided gate oxide layer; and
a computer in communication with the film thickness measuring device;
wherein the computer is adapted to: monitor the thickness of the oxidized nitrided gate oxide layer after an oxidation step conducted in the furnace; store the measured thickness values collected from the thickness measuring device in memory; and retrieve and analyze the measured thickness values.

21. The system of claim 20, wherein the computer is adapted to calculate process control limits from the measured film thickness data.

22. The system of claim 21, further comprising an alarm adapted to indicate when the measured film thickness exceeds the process control limits.
